(19) United States
(12) Patent Application Publication
(10) Pub. No.: US 2026/0106578 A1
(43) Pub. Date: Apr. 16, 2026

(54) HIGH FREQUENCY AMPLIFIER

(71) Applicant: SAMSUNG ELECTRONICS CO., LTD., Suwon-si (KR)

(72) Inventors: Ickhyun SONG, Seoul (KR); Jongho LEE, Seoul (KR); Taeyeong KIM, Seoul (KR)

(73) Assignees: SAMSUNG ELECTRONICS CO., LTD., Suwon-si (KR); IUCF-HYU(INDUSTRY-UNIVERSITYCOOPERATIONFOUNDATIONHANYANG UNIVERSITY), Seoul (KR)

(21) Appl. No.: 19/327,609

(22) Filed: Sep. 12, 2025

(30) Foreign Application Priority Data
Oct. 10, 2024 (KR) 10-2024-0137277

(51) Int. Cl. H03F 3/19

(52) U.S. Cl. CPC H03F 3/19; H03F 2200/165; H03F 2200/171; H03F 2200/451

(57) ABSTRACT

A high-frequency amplifier includes: a first transistor including a first gate, a first drain, and a first source, wherein the first transistor is configured to receive a high-frequency input signal from an antenna connected to the first gate; a second transistor including a second gate, a second drain, and a second source, wherein the second transistor is connected to the first transistor according to a cascode structure, and is configured to output a high-frequency output signal to the second drain; a first inductor connected to the first gate and a ground node; a second inductor connected to the second drain and the ground node; and a filter circuit connected to at least one of the second gate and an intermediate node, wherein the intermediate node is connected to the first drain and the second source, and wherein the filter circuit includes a capacitor.

### CROSS-REFERENCE TO RELATED APPLICATION(S)

This application is based on and claims priority under 35 USC 119(a) to Korean Patent Application No. 10-2024-0137277, filed on Oct. 10, 2024 in the Korean Intellectual Property Office, the disclosure of which is incorporated by reference herein in its entirety.

### BACKGROUND

### 1. Field

The present disclosure relates to a high frequency amplifier.

### 2. Description of Related Art

A high-frequency amplifier may be used in a wireless communication device to transmit and receive data using wireless signals in a high-frequency band, and may be connected to an antenna to amplify a high-frequency input signal generated by the antenna and output a high-frequency output signal. Because data included in the wireless signal may be restored from the high-frequency output signal, it may be desirable to secure the performance of a high-frequency amplifier regardless of a wireless communication environment. For high-frequency amplifier used in communication satellites or aerospace fields, there may be a high possibility that the high-frequency amplifier will be affected by high-energy particles generated by spacecraft, or the like, and a single event transient phenomenon generated by high-energy particles may reduce the reliability of the high-frequency amplifier and, in some cases, cause permanent damage to the high-frequency amplifier. Therefore, various methods for securing the reliability of the high-frequency amplifier, and stably maintaining the performance thereof, have been proposed.

### SUMMARY

Provided is a high-frequency amplifier for improving reliability and performance by reducing the influence of transient current generated by a single-event transient phenomenon, or the like.

Additional aspects will be set forth in part in the description which follows and, in part, will be apparent from the description, or may be learned by practice of the presented embodiments.

In accordance with an aspect of the disclosure, a high-frequency amplifier includes: a first transistor including a first gate, a first drain, and a first source, wherein the first transistor is configured to receive a high-frequency input signal from an antenna connected to the first gate; a second transistor including a second gate, a second drain, and a second source, wherein the second transistor is connected to the first transistor according to a cascode structure, and is configured to output a high-frequency output signal to the second drain; a first inductor connected to the first gate and a ground node; a second inductor connected to the second drain and the ground node; and a filter circuit connected to at least one of the second gate and an intermediate node, wherein the intermediate node is connected to the first drain and the second source, and wherein the filter circuit includes a capacitor.

In accordance with an aspect of the disclosure, a high-frequency amplifier includes: a first transistor including a first gate connected to an input terminal configured to receive a high-frequency input signal, a first drain, and a first source connected to a ground node; a second transistor including a second gate, a second drain, and a second source connected to the first drain, wherein the second drain is connected to a power node configured to supply a predetermined power voltage, and to an output terminal configured to output a high-frequency output signal; a first inductor connected to the input terminal and the ground node; and a second inductor connected to the output terminal and the ground node.

In accordance with an aspect of the disclosure, a high-frequency amplifier includes: a first transistor including a first gate connected to an input terminal configured to receive a high-frequency input signal, a first drain, and a first source connected to a ground node; a second transistor including a second gate, a second drain, and a second source connected to the first drain, wherein the second drain is connected to a power node configured to supply a predetermined power voltage and an output terminal configured to output a high-frequency output signal; a first filter circuit including a first capacitor connected to an intermediate node, and a first filter inductor connected to the first capacitor and the ground node, wherein the intermediate node is connected to the first drain and the second source; and a second filter circuit including a second capacitor connected to the second gate and the ground node.

### BRIEF DESCRIPTION OF DRAWINGS

The above and other aspects, features, and advantages of the present disclosure will be more apparent from the following detailed description, taken in conjunction with the accompanying drawings, in which:

FIG. 1 is a drawing provided to explain a communication environment in which a high-frequency amplifier may be used, according to an example embodiment;

FIG. 2 is a block diagram schematically illustrating a wireless communication device including a high-frequency amplifier according to an example embodiment;

FIG. 3 is a block diagram schematically illustrating a high-frequency amplifier according to an example embodiment;

FIG. 4 is a circuit diagram schematically illustrating a high-frequency amplifier according to an example embodiment;

FIGS. 5 and 6 are drawings provided to illustrate an operation of a high-frequency amplifier according to an example embodiment;

FIGS. 7 and 8 are circuit diagrams schematically illustrating a high-frequency amplifier according to an example embodiment;

FIGS. 9 and 10 are drawings provided to illustrate an operation of a high-frequency amplifier according to example embodiment; and

FIG. 11 is a circuit diagram schematically illustrating a high-frequency amplifier according to example embodiment.

### DETAILED DESCRIPTION

Hereinafter, example embodiments are described with reference to the attached drawings.

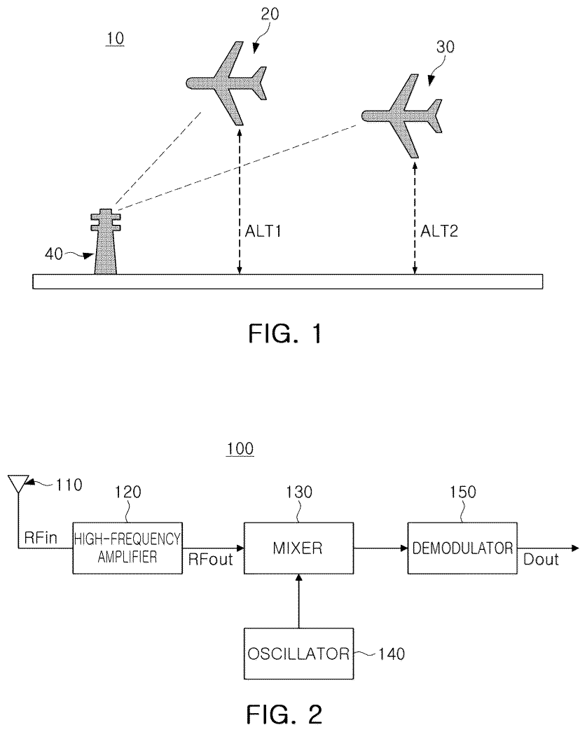

FIG. 1 is a drawing provided to illustrate a communication environment in which a high-frequency amplifier may be used, according to an example embodiment.

Referring to FIG. 1, the high-frequency amplifier according to an example embodiment may be applied to or included in a communication environment 10 transmitting and receiving wireless signals at relatively high altitudes (e. g, a first altitude ALT1 and a second altitude ALT2) above the ground. The communication environment 10 according to an example embodiment described with reference to FIG. 1 may be an environment in which a plurality of aircraft (e.g., an aircraft 20 and an aircraft 30) may communicate with a ground control tower 40 by transmitting and receiving wireless signals in a high-frequency band.

Each of the aircraft 20 and 30 may fly at a relatively high altitude. For example, a cruising altitude of the aircraft may be up to ten thousand meters or more. At the altitude at which the aircraft 20 and 30 fly, the influence of radiation, or the like, may be relatively greater than on the ground. The intensity of radiation to which the aircraft 20 and 30 are exposed may be affected by a latitude, longitude, and altitude of a route on which the aircraft 20 and 30 are flying.

Radiation may generate high-energy particles such as thermal neutrons, fast neutrons, and the like, and when such high-energy particles collide with equipment mounted on the aircraft 20 and 30, various problems may occur. For example, for communication with a control tower 10, or communication between the aircraft 20 and 30, each of the aircraft 20 and 30 may be equipped with a high-frequency amplifier, and the high-frequency amplifier may include at least one semiconductor device such as a transistor. When the high-energy particles as described above collide with a semiconductor device included in a high-frequency amplifier, a single event transient phenomenon, or the like, may occur, and transient current may be temporarily generated in the semiconductor device. The transient current may act as noise on a high-frequency input signal, a high-frequency output signal of the high-frequency amplifier, or may cause fluctuations in a DC bias voltage, or the like, input to the operation of the high-frequency amplifier, which may temporarily deteriorate the performance of the high-frequency amplifier and the wireless communication device including the high-frequency amplifier, or in severe cases, cause permanent damage.

In an example embodiment, in order to solve the above-described problem, embodiments of the present disclosure may relate to a high-frequency amplifier which may sufficiently secure reliability and performance even when a single event transient phenomenon occurs. The high-frequency amplifier according to an example embodiment may include a circuit element that may be connected between a specific node and a ground node, and that may be configured to rapidly discharge transient current generated by a single event transient phenomenon to the ground node. According to example embodiments, a circuit element providing a discharge path for the transient current may be connected to at least one of an input terminal of the high frequency amplifier, an output terminal, and a node configured to supply a DC bias voltage to the high-frequency amplifier.

FIG. 2 is a block diagram schematically illustrating a wireless communication device including a high-frequency amplifier according to an example embodiment.

Referring to FIG. 2, a wireless communication device 100 according to an example embodiment may include an antenna 110, a high-frequency amplifier 120, a mixer 130, an oscillator 140, a demodulator 150, and the like. The antenna 110 may convert electromagnetic waves having frequencies in a specific frequency band into a wireless signal, and provide the signal as a high-frequency input signal RFin to the high-frequency amplifier 120. In an example embodiment, the antenna 110 may generate a high-frequency input signal RFin having a frequency a high frequency band of several gigahertz or more, and provide the signal to the high-frequency amplifier 120.

In an example embodiment, a peak-to-peak value of high-frequency input signal RFin input to the high-frequency amplifier 120 may be in a range of tens to hundreds of microvolts. The high-frequency amplifier 120 may be designed as a low noise amplifier for lowering an overall noise figure of the high-frequency input signal RFin, but embodiments are not limited thereto. The high-frequency amplifier 120 may output a high-frequency output signal RFout amplifying a high-frequency input signal RFin to a mixer 130.

The mixer 130 may function as a frequency down converter, and may be configured to down-convert a frequency of a high-frequency output signal RFout. For example, the mixer 130 may down-convert the frequency of the high-frequency output signal RFout using a signal provided by an oscillator 140. In an example embodiment, the oscillator 140 may provide a signal having the same frequency as a carrier signal to the mixer 130.

The demodulator 150 may extract data Dout transmitted by a side of transmitter by including the signal in a carrier signal from a signal of which the frequency has been down-converted by the mixer 130. According to an example embodiment, an analog filter, a variable gain amplifier, and the like, may be connected between the demodulator 150 and the mixer 130, and the analog filter may include at least one of a high pass filter and a band pass filter.

When a wireless communication device 100 operates in a communication environment into which high-energy particles may be introduced, a transient current may be generated due to a single event transient phenomenon, or the like, as described above with reference to FIG. 1. In an example embodiment, this may occur in aircraft flying at high altitude and communication satellites, and also in wireless communication devices 100 employed in nuclear power plants, research institutes, or military equipment in which strong radiation exists.

When a single event transient phenomenon is generated due to high-energy particles, transient current may flow in a semiconductor device such as a transistor, or the like, included in the high-frequency amplifier 120. The transient current may be reflected in the high-frequency input signal RFin, the high-frequency output signal RFout, and the like, and may affect the performance of the wireless communication device 100. In addition, when transient current occurs which exceeds the maximum current that the semiconductor device can withstand, temporary or permanent damage may occur to the high-frequency amplifier 120, which may shorten the life of the wireless communication device 100.

In an example embodiment, a circuit element for rapidly discharging transient current may be included in the high-frequency amplifier 120. For example, the circuit element for discharging transient current may be connected between a node of the high-frequency amplifier 120 and a ground node, and may include a capacitor or an inductor. For example, an inductor for passing transient current having DC characteristics or low-frequency characteristics to the ground node may be connected to an input terminal into which a high-frequency input signal RFin may be introduced and an output terminal outputting a high-frequency output signal RFout. In addition, as another example, a capacitor may be connected to a node which may receive a DC bias voltage used for the operation of a high-frequency amplifier 120, so that the DC bias voltage is not discharged to the ground node together with the transient current.

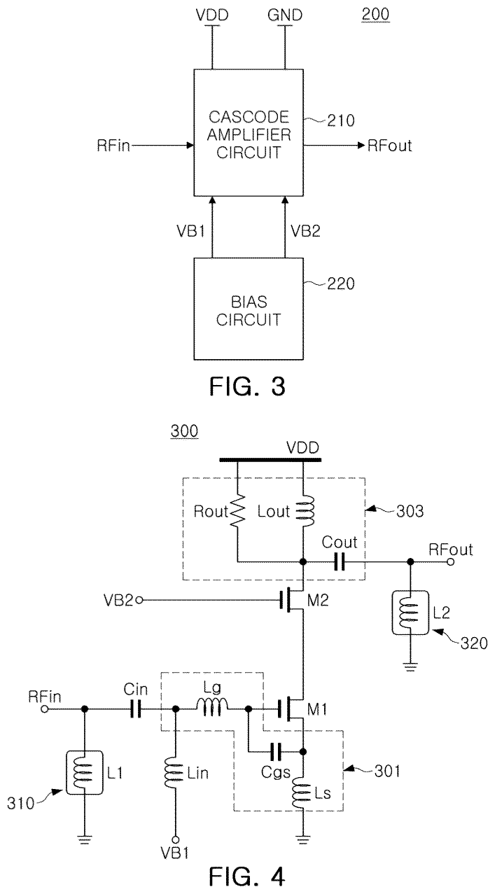

FIG. 3 is a block diagram schematically illustrating a high-frequency amplifier according to an example embodiment.

Referring to FIG. 3, a high-frequency amplifier 200 according to an example embodiment may include a cascode amplifier circuit 210 and a bias circuit 220. The cascode amplifier circuit 210 may include transistors connected according to a cascode structure, and may be operated by a ground voltage GND, a power supply voltage VDD, and bias voltages (e.g., a first bias voltage VB1, and a second bias voltage VB2). The cascode amplifier circuit 210 may amplify a high-frequency input signal RFin received from an antenna or the like and output a high-frequency output signal RFout.

For example, the cascode amplifier circuit 210 may include a first transistor and a second transistor connected in series between a power node configured to supply a power voltage VDD and a ground node configured to supply a ground voltage GND. The high-frequency input signal RFin may be input to a gate of the first transistor, and the high-frequency output signal RFout may be output from a drain of the second transistor. In addition, the cascode amplifier circuit 210 may include an impedance matching circuit, and the matching circuit may include at least a portion of a resistor, an inductor, and a capacitor.

The bias circuit 220 may supply bias voltages to at least one of the first transistor and the second transistor. For example, the first bias voltage VB1 may be input to the gate of the first transistor, and the second bias voltage VB2 may be input to the gate of the second transistor.

FIG. 4 is a circuit diagram schematically illustrating a high-frequency amplifier according to an example embodiment.

Referring to FIG. 4, a high-frequency amplifier 300 according to an example embodiment may include a first transistor M1, a second transistor M2, an input capacitor Cin, an input inductor Lin, a first matching circuit 301, a second matching circuit 303, a first inductor L1, a second inductor L2, and the like. Each of the first transistor M1 and the second transistor M2 may be or may include an N-type metal oxide semiconductor (NMOS) transistor, and the first transistor M1 and second transistor M2 may be connected according to a cascode structure to provide a cascode amplifier.

A source of the first transistor M1 may be connected to a ground node, and a drain may be connected to a source of the second transistor M2. A high-frequency input signal RFin and a first bias voltage VB1 may be input to the gate of the first transistor M1. The first transistor M1 may be configured to operate as a common source amplifier.

The first matching circuit 301 may include a gate inductor Lg, a gate-source capacitor Cgs, and a source inductor Ls. A first bias voltage VB1 may be applied to a gate of the first transistor M1 through an input inductor Lin, and a high-frequency input signal RFin may be applied to the gate of the first transistor M1 through an input capacitor Cin. By the input capacitor Cin, a DC component included in the high-frequency input signal RFin may be blocked. In order to prevent the first bias voltage VB1 having DC voltage characteristics from being blocked by the input capacitor Cin, the input capacitor Cin may not be connected between the gate of the first transistor M1 and the input inductor Lin.

A drain of the second transistor M2 may be connected to a second matching circuit 303. The second matching circuit 303 may include an output inductor Lout, an output resistor Rout, and an output capacitor Cout, and the output inductor Lout and the output resistor Rout may be connected between a power node configured to supply a power voltage VDD and the drain of the second transistor M2. According to embodiments, the output capacitor Cout may be connected between an output terminal from which a high-frequency output signal RFout is output and the drain of the second transistor M2. The DC component included in the high-frequency output signal Rout may be filtered by the output capacitor Cout.

A second bias voltage VB2 may be input to the gate of the second transistor M2. Current flowing through the second transistor M2 may be controlled by a second bias voltage VB2, and for example, the second bias voltage VB2 may be controlled to control a constant amount of current to flow through the second transistor M2. When the first transistor M1 operating as a common source stage amplifies and outputs a high-frequency amplified signal RFin, the second transistor M2 may further amplify the output of the first transistor M1 to generate a high-frequency output signal RFout. The second transistor M2 may be configured to operate as a common gate amplifier. The second bias voltage VB2 may be a voltage provided from a bias circuit together with the first bias voltage VB1.

Referring to FIG. 4, a choke circuit 310 may be connected to an input terminal IN into which a high-frequency input signal RFin may be input, and a choke circuit 320 may be connected to an output terminal OUT from which a high-frequency output signal RFout may be output. In an example embodiment illustrated in FIG. 4, a first choke circuit 310 including a first inductor L1 may be connected between the input terminal IN and a ground node, and a second choke circuit 320 including a second inductor L2 may be connected between the output terminal OUT and the ground node.

According to an example embodiment, the first inductor L1 and the second inductor L2 may have the same inductance, and the inductance of each of the first inductor L1 and the second inductor L2 may be determined according to a frequency of the high-frequency input signal RFin. For example, when the high-frequency input signal RFin has a frequency in a several gigahertz band, each of the first inductor L1 and the second inductor L2 may have inductance of several nanohenry (nH). As the frequency of the high-frequency input signal RFin increases, the inductance of each of the first inductor L1 and the second inductor L2 may decrease. Depending on the embodiment, the first inductor L1 and the second inductor L2 may have different levels of inductance.

According to embodiments, an inductor may have impedance proportional to frequency. Therefore, as illustrated in FIG. 4, by connecting the first inductor L1 between the input terminal IN and the ground node, transient currents generated due to a single event transient phenomenon, or the like, having DC characteristics may be removed through the ground node. In addition, through the second inductor L2 connected between the output terminal OUT and the ground node, transient current generated by a single event transient phenomenon, or the like, may be removed through the ground node. Therefore, the influence of transient currents generated due to various causes including high-energy particles on the high-frequency input signal RFin and high-frequency output signal RFout may be minimized. As a result, the reliability, performance, and lifespan of a high-frequency amplifier 300 and a wireless communication device including the high-frequency amplifier 300 may be improved.

The high-frequency amplifier 300 according to an example embodiment illustrated in FIG. 4 is not limited to being applicable only to a wireless communication device adopted in a communication environment having a high probability of the generation high-energy particles. For example, when it is desired to implement a wireless communication device having high reliability and long lifespan regardless of the communication environment, a high-frequency amplifier 300 may also be applied to, or included in, an analog circuit in a general communication environment.

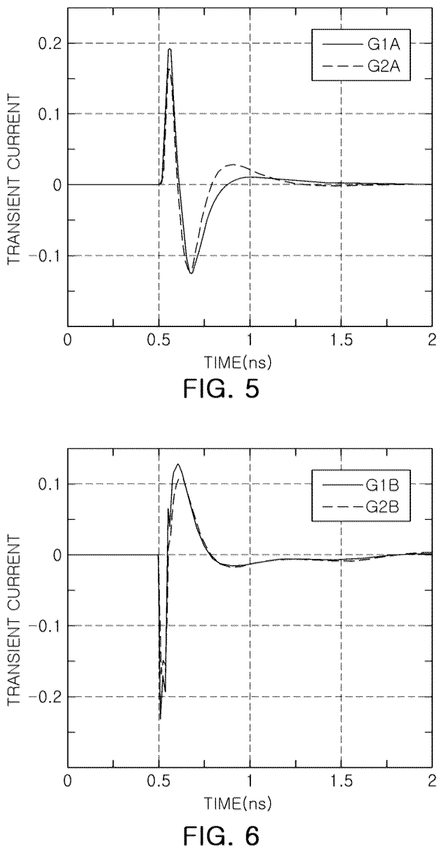

FIGS. 5 and 6 are drawings provided to illustrate an operation of a high-frequency amplifier according to an example embodiment.

FIGS. 5 and 6 may be drawings provided to illustrate an operation of a high-frequency amplifier 300 described with reference to FIG. 4 above. Hereinafter, an example of the operation of the high-frequency amplifier 300 is described with reference to FIG. 4.

In FIG. 5, the first graph G1A may be a graph showing results of simulating a transient current generated due to a single event transient phenomenon, or the like, and flowing into the input terminal IN, in a high-frequency amplifier having a structure not including a first inductor L1. In addition, the second graph G2A may be a graph showing results of simulating a transient current generated due to a single event transient phenomenon, or the like, and flowing into the input terminal IN, in a high-frequency amplifier 300 including a first inductor L1, as illustrated in FIG. 4. The transient current corresponding to in FIG. 5 may flow into the gate of the first transistor M1 and affect the high-frequency input signal RFin.

Each of the first graph G1A and the second graph G2A may be a graph corresponding to a case in which transient current generated from a current source modeled using parameters such as a raising time, falling time, maximum current value, and total charge amount, and the like, extracted using TCAD simulation flows into an input terminal IN. In comparison with the first graph G1A, the second graph G2A may show that a peak value of the transient current may be reduced in the high-frequency amplifier 300 in which the first inductor L1 is connected to the input terminal IN.

Next, the first graph G1B of FIG. 6 may be a graph showing results of simulating a transient current generated due to a single event transient phenomenon, or the like, and flowing into an output terminal OUT, in a high-frequency amplifier having a structure not including a second inductor L2. According to embodiments, the second graph G2B may be a graph showing results of simulating a transient current generated due to a single event transient phenomenon, or the like, and flowing into the output terminal OUT, in a high-frequency amplifier 300 including a second inductor L2, as illustrated in FIG. 4.

The transient current simulated in FIG. 6 may flow into the drain of the second transistor M2 and affect the high-frequency output signal RFout. In comparison with the first graph G1B, the second graph G2B of FIG. 6 may show that both a positive peak value and a negative peak value of the transient current may be reduced in a high-frequency amplifier 300 in which the second inductor L2 is connected to the output terminal OUT.

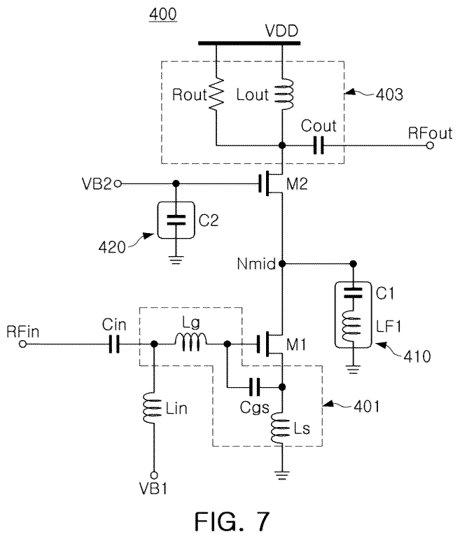

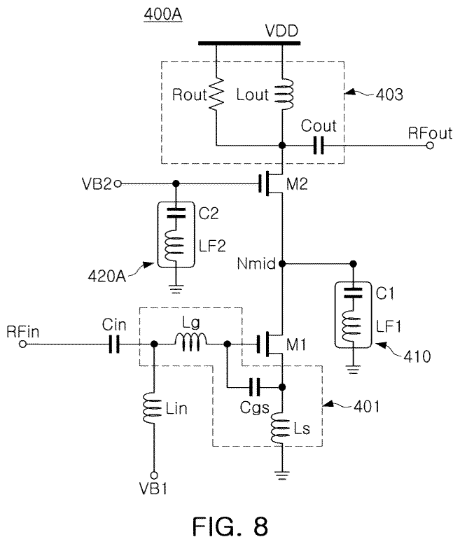

FIGS. 7 and 8 are circuit diagrams illustrating a high-frequency amplifier according to an example embodiment.

Referring to FIG. 7, a high-frequency amplifier 400 according to an example embodiment may include a first transistor M1, a second transistor M2, an input capacitor Cin, an input inductor Lin, a first matching circuit 401, a second matching circuit 403, a first filter circuit 410, a second filter circuit 420, and the like. Each of the first transistor M1 and the second transistor M2 may be or may include an NMOS transistor, and the first transistor M1 and second transistor M2 may be connected according to a cascode structure to provide a cascode amplifier.

The configuration of the first transistor M1, the second transistor M2, the input capacitor Cin, the input inductor Lin, the first matching circuit 401, and the second matching circuit 403 may be similar to those included in the high-frequency amplifier 300 according to the embodiment described above with reference to FIG. 4. However, a high frequency amplifier 400 according to an example embodiment illustrated in FIG. 7 may include a first filter circuit 410 connected to a drain of a first transistor M1 and a source of a second transistor M2, and a second filter circuit 420 connected to a gate of the second transistor M2.

Referring to FIG. 7, the first filter circuit 410 may include a first capacitor C1 and a first filter inductor LF1 connected in series between an intermediate node Nmid to which the drain of the first transistor M1 and the source of the second transistor M2 are connected, and a ground node. According to embodiments, the second filter circuit 420 may include a second capacitor C2 connected between the gate of the second transistor M2 and the ground node. Therefore, in the embodiment illustrated in FIG. 7, the first filter circuit 410 and the second filter circuit 420 may have different structures. One electrode of the second capacitor C2 may be connected to the gate of the second transistor M2, and the other electrode of the second capacitor C2 may be connected to the ground node.

The first filter circuit 410 may have a similar function to the first inductor L1 and the second inductor L2 described above with reference to FIG. 4. For example, the first transistor M1, which may be a common source stage, may be configured to amplify a high-frequency input signal RFin and output the signal to the drain. When transient current due to a single event transient phenomenon, or the like, flows into the drain of the first transistor M1 or the source of the second transistor M2, the transient current may be quickly removed through the ground node by the first filter circuit 410. Therefore, the influence of transient current may be minimized on a signal that is generated by the first transistor M1 by amplifying the high-frequency input signal RFin and that is output to the second transistor M2.

The second filter circuit 420 may reduce the influence of transient current on a second bias voltage VB2 under the condition that the transient current flows into the gate of the second transistor M2. However, to prevent the second bias voltage VB2, which may be a DC voltage, from leaking to the ground node by the second filter circuit 420, the second filter circuit 420 may include a second capacitor C2 having an electrode directly connected to the gate of the second transistor M2. Because the second capacitor C2 may block the DC component, the second bias voltage VB2 may be normally applied to the gate of the second transistor M2, rather than the second filter circuit 420, and only the transient current generated by external influence may be removed through the ground node.

Referring to FIG. 8, a high-frequency amplifier 400A according to an example embodiment may include a first transistor M1, a second transistor M2, an input capacitor Cin, an input inductor Lin, a first matching circuit 401, a second matching circuit 403, a first filter circuit 410, a second filter circuit 420, and the like. Each of the first transistor M1 and the second transistor M2 may be an NMOS transistor, and the first transistor M1 and the second transistor M2 may be connected according to a cascode structure to provide a cascode amplifier. The first transistor M1 may be configured to operate as a common source amplifier, and the second transistor M2 may be configured to operate as a common gate amplifier.

The configuration of the first transistor M1, the second transistor M2, the input capacitor Cin, the input inductor Lin, the first matching circuit 401, the second matching circuit 403, and the first filter circuit 410 may be similar to that of the high-frequency amplifier 400 according to the embodiment described above with reference to FIG. 7. However, in the high-frequency amplifier 400A according to the embodiment illustrated in FIG. 8, a second filter circuit 420A connected to a gate of the second transistor M2 may include a second capacitor C2 and a second filter inductor LF2. Therefore, the first filter circuit 410 and the second filter circuit 420A may have the same structure.

The first filter inductor LF1 and the second filter inductor LF2 may have the same inductance, and the first capacitor C1 and the second capacitor C2 may also have the same capacitance. However, depending on the embodiment, the first filter inductor LF1 and the second filter inductor LF2 may have different levels of inductance. In addition, the first capacitor C1 and the second capacitor C2 may also have different levels of capacitance.

In a cascode amplifier, the first transistor M1 provided as a common source stage may connected in series with the second transistor M2 provided as a common gate stage, so it may be beneficial to prevent signal distortion at the intermediate node Nmid at which the first transistor M1 and the second transistor M2 are connected. In the embodiments shown in FIGS. 7 and 8, a first filter circuit 410 may be connected between the middle node Nmid and the ground node to reduce distortion of a high-frequency signal transmitted from a common source stage to a common gate stage.

When a level of the second bias voltage VB2 input to the gate of the second transistor M2 operating as a common gate stage fluctuates due to transient current, the current flowing through the second transistor M2 may also fluctuate, and as a result thereof, a high-frequency output signal RFout may be distorted. In the embodiments illustrated in FIGS. 7 and 8, by stably maintaining the second bias voltage VB2 using the second filter circuits 420 and 420A, the distortion of the high-frequency output signal RFout may be minimized. Therefore, the influence of transient current generated due to various causes including high-energy particles on the frequency output signal RFout may be minimized, and the reliability, performance, and lifespan of the high-frequency amplifiers 400 and 400A and a wireless communication device including at least one of the high-frequency amplifiers 400 and 400A may be improved.

As described with reference to FIG. 4, the high-frequency amplifiers 400 and 400A according to the embodiments described with reference to FIGS. 7 and 8 are not limited to being applicable only to a wireless communication device adopted in a communication environment with a high possibility of high-energy particle generation. For example, by applying the high-frequency amplifiers 400 and 400A according to an example embodiment to a wireless communication device in a general communication environment, the reliability, performance, lifespan, and the like, of the wireless communication device may be improved.

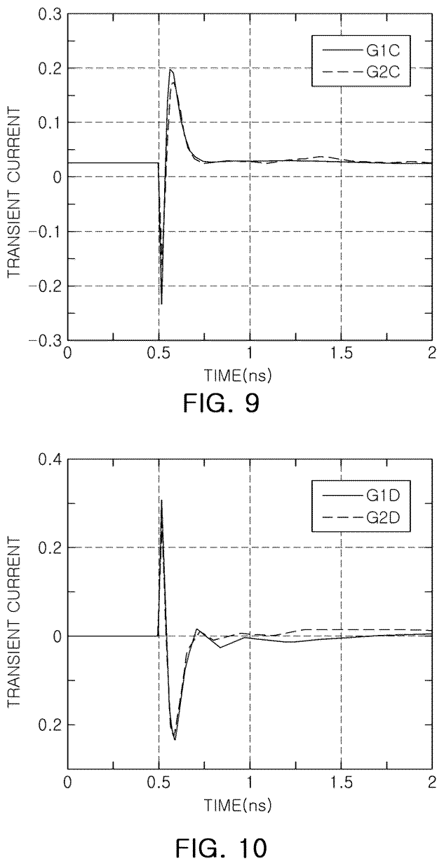

FIGS. 9 and 10 are drawings provided to illustrate an operation of a high-frequency amplifier according to an example embodiment.

FIGS. 9 and 10 may be drawings provided to illustrate an operation of a high-frequency amplifier 400A described above with reference to FIG. 8. Hereinafter, an example of the operation of the high-frequency amplifier 300 is explained with reference to FIG. 8.

In FIG. 9, a first graph G1C may be a graph showing results of simulating a transient current generated due to a single event transient phenomenon, or the like, and flowing into an intermediate node Nmid in a high-frequency amplifier having a structure not including a first filter circuit 410. In addition, a second graph G2C may be a graph showing results of simulating a transient current generated due to a single event transient phenomenon, or the like, and flowing into an intermediate node Nmid in a high-frequency amplifier 400A including a first filter circuit 410, as illustrated in FIG. 8.

Each of the first graph G1C and the second graph G2C may be a graph corresponding to a case in which transient current generated from a current source modeled using parameters such as a raising time, falling time, maximum current value, and total charge amount, and the like, extracted using TCAD simulation flows into an input terminal IN. In comparison with the first graph G1C, the second graph G2 may show that both a positive peak value and a negative peak value of the transient current may be reduced in the high-frequency amplifier 400A in which the first filter circuit 410 is connected to the intermediate node Nmid.

Next, in an example corresponding to a high-frequency amplifier having a structure not including a second filter circuit 420A, the first graph G1D of FIG. 10 may be a graph showing results of simulating a transient current generated due to a single event transient phenomenon, or the like, and flowing into a gate of the second transistor M2. In addition,, in an example corresponding to a high-frequency amplifier 400A including a second filter circuit 420A as illustrated in FIG. 8, the second graph G2D may be a graph showing results of simulating a transient current generated due to a single event transient phenomenon, or the like, and flowing into the gate of the second transistor M2.

In comparison with the first graph G1D, the second graph G2D may show that a peak value of the transient current may be reduced in a high-frequency amplifier 400A in which a second filter circuit 420A is connected to the gate of a second transistor M2. As described with reference to FIGS. 9 and 10, by connecting the first filter circuit 410 and the second filter circuit 420A to the high-frequency amplifier 400A, the second transistor M2 may be stably biased and distortion of a high-frequency signal output from the first transistor M1 to the second transistor M2 may be reduced.

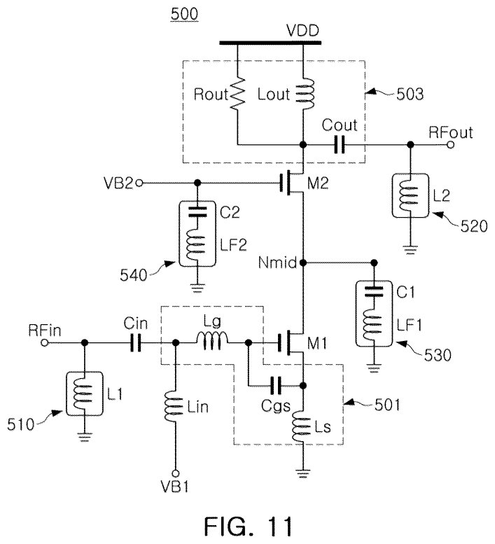

FIG. 11 is a circuit diagram schematically illustrating a high-frequency amplifier according to an example embodiment.

Referring to FIG. 11, a high-frequency amplifier 500 according to an example embodiment may include a first transistor M1, a second transistor M2, an input capacitor Lin, a first matching circuit 501, a second matching circuit 503, a first inductor L1, a second inductor L2, a first filter circuit 530, a second filter circuit 540, and the like.

Each of the first transistor M1 and the second transistor M2 may be an NMOS transistor, and the first transistor M1 and the second transistor M2 may be connected according to a cascode structure to provide a cascode amplifier. The first transistor M1 may be configured to provide a common source stage, and the second transistor M2 may be configured to provide a common gate stage. The configuration such as the first transistor M1, the second transistor M2, the input capacitor Cin, the input inductor Lin, the first matching circuit 401, the second matching circuit 403, and the like, may be similar to the embodiments described above with reference to FIGS. 4, 7, and 8. However, the high-frequency amplifier 500 according to an example embodiment illustrated in FIG. 11 may include a first choke circuit 510 connected to the input terminal IN, a second choke circuit 520 connected to the output terminal OUT, a first filter circuit 530 connected to the intermediate node Nmid, and a second filter circuit 540 connected to a gate of the second transistor M2.

The first choke circuit 510 may include a first inductor L1 and the second choke circuit 520 may include a second inductor L2. The functions of each of the first inductor L1 and the second inductor L2 530 may be similar to those described above with reference to FIG. 4. For example, the first inductor L1 may be introduced into the input terminal IN and may remove transient current having DC characteristics or low-frequency characteristics through a ground node. The second inductor L2 may be output to the output terminal OUT together with a high-frequency output signal RFout and may remove transient current having DC characteristics or low-frequency characteristics through the ground node.

The first filter circuit 530 may include a first capacitor C1 and a first filter inductor LF1, and the second filter circuit 540 may include a second capacitor C2 and a second filter inductor LF2. The functions of each of the first filter circuit 530 and the second filter circuit 540 may be similar to those described above with reference to FIGS. 7 and 8. For example, the first filter circuit 530 may be configured to reduce transient current flowing into a drain of the first transistor M1 and/or a source of the second transistor M2. The second filter circuit 540 may be configured to reduce transient current flowing into a gate of the second transistor M2 to which a second bias voltage VB2 is input.

As set forth above, according to an example embodiment, at least one of an inductor and a capacitor may be connected to an input terminal, an output terminal of a high-frequency amplifier, a node to which a direct current (DC) bias voltage is input to the high-frequency amplifier, and the like.

Noise components, generated by a single event transient phenomenon, or the like, and having DC characteristics or low-frequency characteristics may be removed through a ground node, and the influence of additional circuit elements on a high-frequency input signal and high-frequency output signal in a high-frequency band including data may be minimized. Therefore, the reliability, performance, and the like, of the high-frequency amplifier may be improved.

The various and beneficial advantages and effects are not limited to the above-described examples, and may be more easily understood through description of specific embodiments.

While example embodiments are described above, it will be apparent to those skilled in the art that modifications and variations could be made without departing from the scope of the disclosure, as defined by the appended claims.

What is claimed is:

1. A high-frequency amplifier, comprising:
a first transistor comprising a first gate, a first drain, and a first source, wherein the first transistor is configured to receive a high-frequency input signal from an antenna connected to the first gate;
a second transistor comprising a second gate, a second drain, and a second source, wherein the second transistor is connected to the first transistor according to a cascode structure, and is configured to output a high-frequency output signal to the second drain;
a first inductor connected to the first gate and a ground node;
a second inductor connected to the second drain and the ground node; and
a filter circuit connected to at least one of the second gate and an intermediate node,
wherein the intermediate node is connected to the first drain and the second source, and
wherein the filter circuit comprises a capacitor.

2. The high-frequency amplifier of claim 1, wherein an inductance of the first inductor is equal to an inductance of the second inductor.

3. The high-frequency amplifier of claim 1, further comprising:
a bias circuit configured to supply a first bias voltage to the first gate, and a second bias voltage to the second gate.

4. The high-frequency amplifier of claim 1, wherein the filter circuit comprises a first filter circuit connected to the intermediate node and a second filter circuit connected to the second gate,
wherein the first filter circuit comprises a first capacitor, and the second filter circuit comprises a second capacitor.

5. The high-frequency amplifier of claim 4, wherein the first filter circuit further comprises a first filter inductor connected to the first capacitor and the ground node.

6. The high-frequency amplifier of claim 4, wherein the second filter circuit further comprises a second filter inductor connected to the second capacitor and the ground node.

7. The high-frequency amplifier of claim 4, wherein a first electrode from included in the second capacitor is connected to the second gate, and a second electrode included in the second capacitor is connected to the ground node.

8. The high-frequency amplifier of claim 1, further comprising:
a first matching circuit connected to the first gate and the first source; and
a second matching circuit connected to the second drain.

9. The high-frequency amplifier of claim 1, wherein the first transistor is configured to operate as a common source amplifier, and
wherein the second transistor is configured to operate as a common gate amplifier.

10. A high-frequency amplifier, comprising:
a first transistor comprising a first gate connected to an input terminal configured to receive a high-frequency input signal, a first drain, and a first source connected to a ground node;
a second transistor comprising a second gate, a second drain, and a second source connected to the first drain, wherein the second drain is connected to a power node configured to supply a predetermined power voltage, and to an output terminal configured to output a high-frequency output signal;
a first inductor connected to the input terminal and the ground node; and
a second inductor connected to the output terminal and the ground node.

11. The high-frequency amplifier of claim 10, further comprising:
an input capacitor connected to the first gate and the input terminal; and
an output capacitor connected to the second drain and the output terminal.

12. The high-frequency amplifier of claim 10, wherein an inductance of the first inductor is equal to an inductance of the second inductor.

13. The high-frequency amplifier of claim 10, further comprising:
a bias circuit configured to supply a first bias voltage to the first gate, and a second bias voltage to the second gate, and
an input inductor connected to a path configured to supply the first bias voltage to the first gate.

14. The high-frequency amplifier of claim 10, wherein each of the first transistor and the second transistor comprises an N-type metal oxide semiconductor (NMOS) transistor.

15. The high-frequency amplifier of claim 10, wherein the first transistor is configured to operate as a common source amplifier, and
wherein the second transistor is configured to operate as a common gate amplifier.

16. A high-frequency amplifier, comprising:
a first transistor comprising a first gate connected to an input terminal configured to receive a high-frequency input signal, a first drain, and a first source connected to a ground node;
a second transistor comprising a second gate, a second drain, and a second source connected to the first drain, wherein the second drain is connected to a power node configured to supply a predetermined power voltage and an output terminal configured to output a high-frequency output signal;
a first filter circuit comprising a first capacitor connected to an intermediate node, and a first filter inductor connected to the first capacitor and the ground node, wherein the intermediate node is connected to the first drain and the second source; and
a second filter circuit comprising a second capacitor connected to the second gate and the ground node.

17. The high-frequency amplifier of claim 16, wherein the second filter circuit comprises only the second capacitor.

18. The high-frequency amplifier of claim 16, wherein the second filter circuit further comprises a second filter inductor connected to the second capacitor and the ground node.

19. The high-frequency amplifier of claim 16, wherein the second gate is configured to receive a predetermined bias voltage.

20. The high-frequency amplifier of claim 16, wherein the first transistor is configured to operate as a common source amplifier, and
wherein the second transistor is configured to operate as a common gate amplifier.
